(19) United States
(12) Patent Application Publication
(10) Pub. No.: US 2018/0082870 A1
(43) Pub. Date: Mar. 22, 2018

(54) ASSEMBLIES AND METHODS OF PROCESS GAS FLOW CONTROL

(71) Applicant: Applied Materials, Inc., Santa Clara, CA (US)

(72) Inventor: Stephen C. Wolgast, Cupertino, CA (US)

(21) Appl. No.: 15/267,231

(22) Filed: Sep. 16, 2016

(51) Int. Cl. H01L 21/67; G05D 7/06; B01D 46/00

(52) U.S. Cl. CPC H01L 21/67253; B01D 2279/45; B01D 46/0002; G05D 7/0676

(57) ABSTRACT

Gas flow control assemblies configured to deliver a gas to a process chamber. The gas flow control assemblies include a single-piece manifold including a manifold body having a length, a first side, and a second side opposite the first side, and passageways extending through the manifold body, the passageways being open to both of the first side and the second side, and no other passageways are formed on any remaining sides, an inlet conduit, an inlet valve, a filter, and an outlet conduit, coupled to one of the first side and the second side, wherein at least some of the inlet conduit, the inlet valve, the filter, the outlet valve, and the outlet conduit are coupled to the first side, and the others are coupled to the second side. Methods and gas panel assemblies for controlling gas flow to a process chamber are described, as are other aspects.

### FIELD

The present disclosure relates to process gas control assemblies for supplying gas to process chambers, and more particularly to process gas control assemblies supplying gas to process chambers for electronic device manufacturing.

### BACKGROUND

In semiconductor processing systems, a substrate (e.g., a silicon-containing wafer, plate, or panel) is processed in a process chamber and the chamber may be provided with a process gas (e.g., a purge gas, an inert gas, or a toxic or flammable gas) which may deliver various compounds, dopants, or etchants to produce or modify semiconductor layers. The flow of each of these gases is controlled by a process gas control assembly (sometimes referred to as a “gas control stick”). These gas control sticks may be assembled together to form a gas panel assembly.

Prior art process gas control assemblies include a manifold that is made up of multiple manifold pieces that may, in some cases, interlock with one another and that may attach to a support piece. The manifold pieces are used to interconnect to valves, filters, mass flow controllers, and conduits of the assemblies. In some cases, the manufacturing method involves forming multiple passages into one or more orthogonal sides of the manifold pieces.

Such manifolds tend to be complicated, difficult to assemble, and expensive to manufacture. Accordingly, the present disclosure is directed at improved process gas control assemblies and methods.

### SUMMARY

In one or more embodiments, a process gas control assembly is provided. The process gas control assembly includes a single-piece manifold including a manifold body having a length, a first side, and a second side opposite the first side, and passageways extending through the manifold body, the passageways being open to both of the first side and the second side, and no other passageways are formed on any remaining sides, an inlet conduit coupled to one of the first side and the second side, an inlet valve coupled to one of the first side and the second side, a filter coupled to one of the first side and the second side, an outlet valve coupled to one of the first side and the second side, and an outlet conduit coupled to one of the first side and the second side wherein at least some of the inlet conduit, inlet valve, the filter, the outlet valve, and the outlet conduit are coupled to the first side, and others of the inlet conduit, inlet valve, the filter, the outlet valve, and outlet conduit are coupled to the second side.

In some embodiments, a gas flow control assembly is provided. The gas flow control assembly includes a single-piece manifold including a manifold body having a length, a first side, and a second side opposite the first side, and passageways extending through the manifold body, the passageways being open on both of the first side and the second side, and no other passageways are formed on any remaining sides, an inlet conduit coupled to a first side, an inlet valve coupled to the second side, a filter coupled to the first side, a first control valve coupled to the second side, a mass flow controller coupled to the first side, a second control valve coupled to the second side, an outlet valve coupled to the first side, and an outlet conduit coupled to the second side.

In further embodiments, a method of assembly of a gas flow control assembly is provided. The method includes providing a single-piece manifold including a manifold body having a length, a first side, and a second side opposite the first side, and passageways extending through the manifold body, the passageways being open to both of the first side and the second side, and no other passageways are formed on any remaining sides, coupling an inlet conduit to one of the first side and the second side, coupling an inlet valve to one of the first side and the second side, coupling a filter to one of the first side and the second side, coupling an outlet valve to one of the first side and the second side, and coupling an outlet conduit to one of the first side and the second side, wherein at least some of the inlet conduit, inlet valve, the filter, the outlet valve, and the outlet conduit are coupled to the first side, and others of the inlet conduit, inlet valve, the filter, the outlet valve, and outlet conduit are coupled to the second side.

Numerous other features are provided in accordance with these and other aspects of the disclosure. Other features and aspects of embodiments of the present disclosure will become more fully apparent from the following description, the appended claims, and the accompanying drawings.

### BRIEF DESCRIPTION OF THE DRAWINGS

FIG. 1A illustrates an isometric view of a gas flow control assembly including a one-piece manifold with dual side-mounted components according to one or more embodiments.

FIG. 1B illustrates an exploded isometric view of a gas flow control assembly including a one-piece manifold with dual side-mounted components according to one or more embodiments.

FIG. 1C illustrates a cross-sectioned side view of a gas flow control assembly including one-piece manifold with dual side-mounted components showing flow paths according to one or more embodiments.

FIG. 2A illustrates an isometric view of a one-piece manifold including passageways formed between the first and second sides thereof and where the orthogonal side are devoid of passageways according to one or more embodiments.

FIG. 2B illustrates a cross-sectioned isometric view of a one-piece manifold including angled passageways formed between the first and second sides thereof according to one or more embodiments.

FIG. 3 illustrates an isometric view of an alternate embodiment of a gas flow control assembly including one-piece manifold with dual side-mounted components according to one or more embodiments.

FIG. 4 illustrates an isometric view of another alternate embodiment of a gas flow control assembly including one-piece manifold with dual side-mounted components according to one or more embodiments.

FIG. 5 illustrates an isometric view of an embodiment of a gas pallet assembly including multiple gas flow control assemblies each including one-piece manifold with dual side-mounted components according to one or more embodiments.

FIG. 6 illustrates a flowchart of a method of assembly of a gas flow control assembly according to one or more embodiments.

### DETAILED DESCRIPTION

In the prior art, internal passages of the manifold pieces of the manifold may be formed, in some embodiments, by drilling passages partway through the manifold body. Lateral passages cross-drilled into one or more orthogonal faces may intersect with the part-way drilled passageways and the ends thereof may be plugged to provide an internal passageway that accommodates flow between components coupled to the manifold. In some embodiments, cross drilling and tight fit between the manifold pieces may involve precision machining. Other embodiments may include passageways connected on the sides and/or ends of the manifold, thus making manufacturing quite difficult and using multiple manufacturing steps.

Each process gas control assembly may include an inlet conduit, an inlet valve, a filter, an outlet valve, and an outlet conduit. If supplying inert gas, toxic gas, or flammable gas, a mass flow controller (MFC) may also be included. Thus, process gas control assemblies, such as for semiconductor processing chambers, attempt to deliver steady flows at precise flow rates, flow ratios, and pressures to one or more process chambers.

The present disclosure provides improved methods and assemblies for controlling gas flow into a process chamber, such as a semiconductor process chamber, or the like. In particular, embodiments of the present disclosure provide dual-sided gas flow control assemblies having compact form factor, that is, the gas flow control assemblies include flow-receiving components (e.g., conduits, valves, filters, and/or MFCs) mounted on both a first side and a second side of a manifold and wherein the assemblies have compact form factor. Compact form factor as used herein means a ratio of overall length (L) to overall width (W) of the individual gas flow control assembly that is very low for those applications where relatively tall assemblies will not fit, such as L/W<10; L/W<8; or even L/W<6 in some embodiments. According to further embodiments, the manifold is a one-piece component and may include machining of flow passages exclusively on first and second opposed side surfaces thereof. The side surfaces orthogonal to the first and second opposed side surfaces may be devoid of flow passages.

Embodiments of the present disclosure may be configured as an inert gas control assembly, a toxic gas or flammable gas control assembly, or a purge gas control assembly.

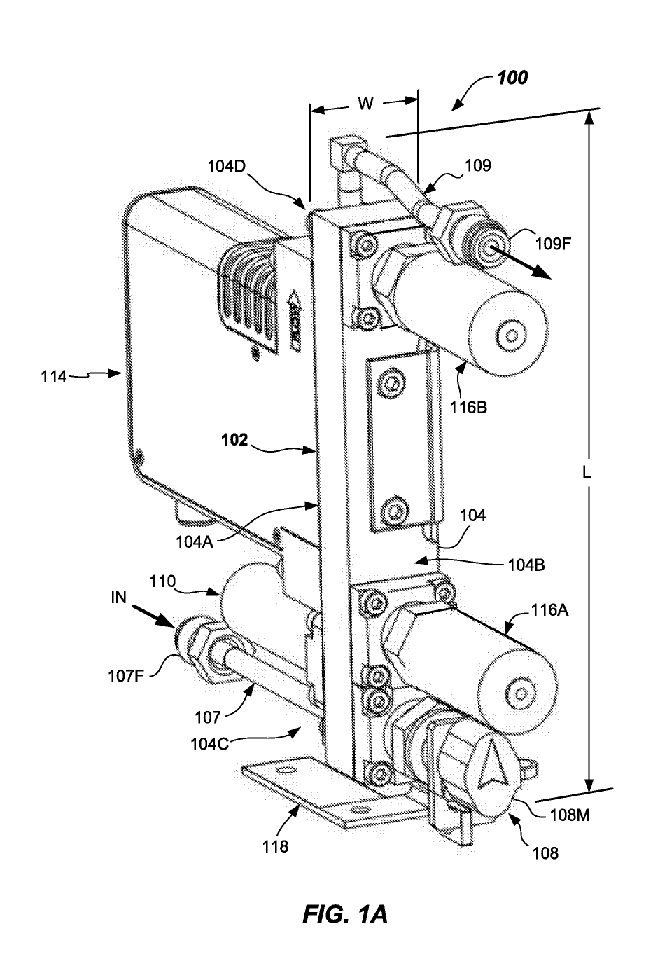

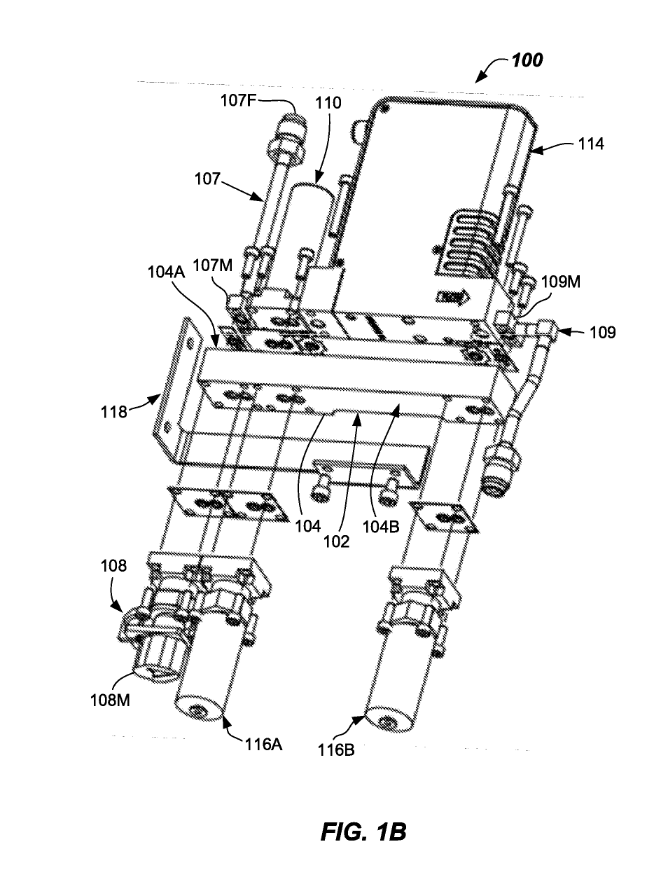

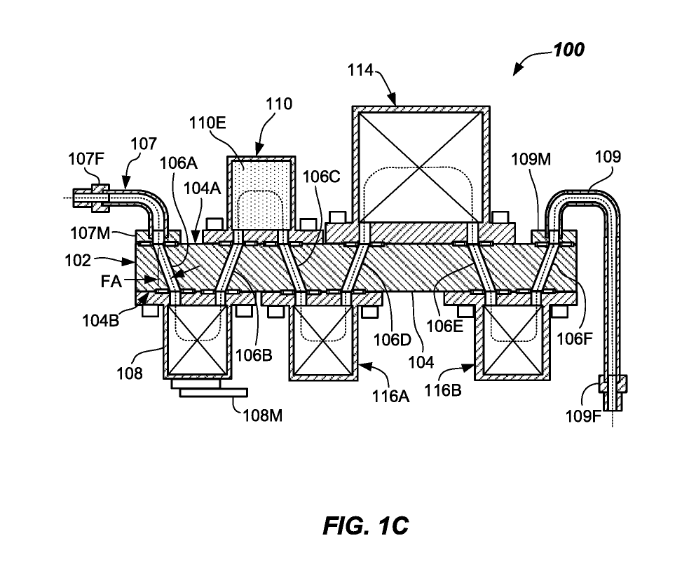

One or more embodiments of the present disclosure provide a novel construction of inlet conduit, inlet valve, filter, outlet valve, and outlet conduit coupled on two opposing sides of a one-piece manifold and first and second sides of the one-piece manifold include flow passages and wherein sides other that the first and second sides of the one-piece manifold do not include flow passages. Example embodiments of gas flow control assemblies and methods of assembly of gas flow control assemblies are described with reference to FIGS. 1A-6 herein below.

Now referring to FIGS. 1A-1C, a first example embodiment of a gas flow control assembly 100 with compact form factor (as described above) according to the present disclosure is depicted. The gas flow control assembly 100 may be used for supplying an inert gas to one or more process chambers or process chamber zones, such as during a deposition or etching operation in semiconductor device manufacture. The inert gas may be a noble gas, such as He, Ar, Ne, or the like. The gas flow control assembly 100 includes, as a foundational building block, a manifold 102 including a manifold body 104 having a length L, a first side 104A, and a second side 104B opposite the first side 104A. The manifold 102 may be made of a one-piece construction and includes multiple passageways (e.g., passageways 106A-106F as shown in FIG. 1B through 1C) that may extend through the manifold body 104 from the first side 104A to the second side 104B. In one or more embodiments, the first side 104A and the second side 104B have machined passageways 106A-106F (flow passageways) formed therein. The other sides (e.g., orthogonal sides) may be devoid of flow passageways.

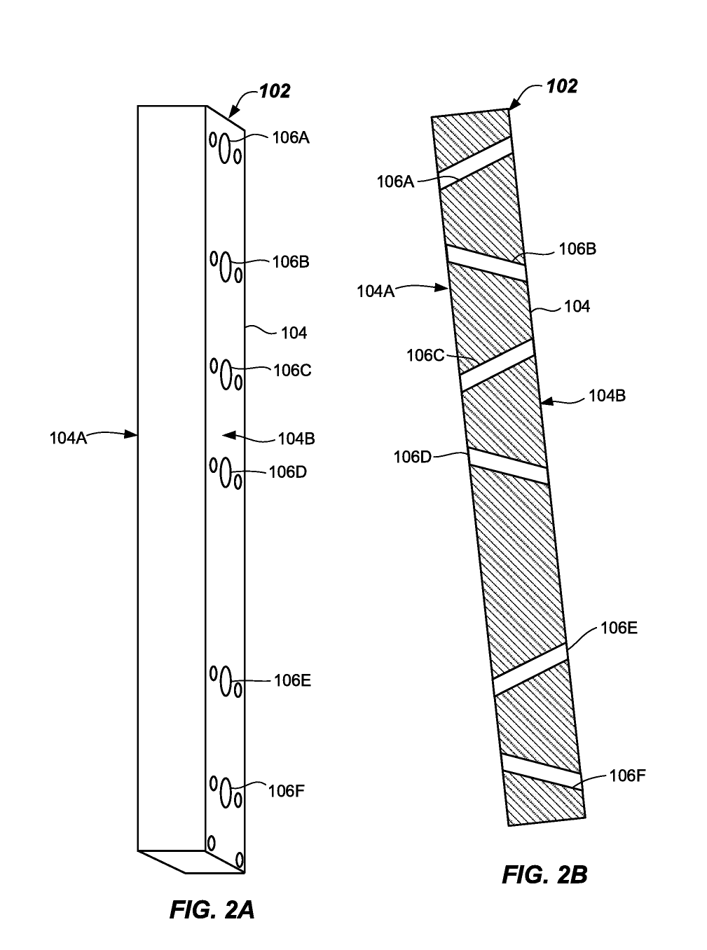

The passageways 106A-106F are open on both of the first side 104A and the second side 104B, as is best shown in FIGS. 1C, 2A and 2B, in order to facilitate gas flow between components mounted on both sides of the manifold 102. As shown in FIGS. 1C and 2B, at least some of the passageways 106A-106F may be oriented so that a central axis thereof is non-perpendicular (i.e., non-normal) to a planar surface of the first side 104A. Likewise, the passageways 106A-106F may be oriented so that a central axis thereof is non-perpendicular (i.e., non-normal) to a surface of the second side 204B. As shown in FIG. 1C, a majority of the passageways 106A-106F may be oriented at an angle (i.e., angled relative to the surface of the first side 104A and the surface of the second side 104B). Some may be straight through in some embodiments. The angled passages may be oriented at an angle of between about 1 degree and 20 degrees relative to the planar surface of the first side 104A and the surface of the second side 104B.

Again referring to FIGS. 1A-1C, the gas flow control assembly 100 may include an inlet conduit 107 coupled to the manifold 102, such as by bolts or screws on a first end 104C. Inlet conduit 107 may include a fitting 107F on a first end, and a mounting block 107M on a second end 104D. The mounting block 107M may be fastened to the manifold body 104 by bolts, screws or the like, for example. The fitting 107F may be coupled or interconnected by another conduit (not shown) to a source of inert gas (not shown), such as a large canister of pressurized inert gas pressurized to about 15 to about 40 psig, for example.

The gas flow control assembly 100 may further include an inlet valve 108 coupled to the manifold 102 at the first end 204C, such as by bolts or screws. Inlet valve 108 may be a manually-controllable valve in some embodiments, which may include a control member 108M (e.g., a handle, lever, or knob) configured to facilitate manual actuation of the inlet valve 108 from a closed to an opened configuration or vice versa, for example. The inlet valve 108 may also be a hybrid valve, which includes both a pneumatic actuator and a control member 108M that is manually actuated by a user (e.g., a handle, lever, or knob) to be used for safety override. The inlet valve 108 may be coupled to one of the first side 104A and the second side 104B, such as to the second side 104B as depicted in FIGS. 1A and 1C. Optionally, inlet valve 108 may be an automated valve with an actuator (electrical, pneumatic, or hydraulic) configured to cause opening and closing of a proportioning valve responsive to signals from a controller. For safety, the inlet valve 108 may include lockout/tagout capabilities.

A filter 110, including a filter element 110E, may be coupled to the manifold 102, such as by bolts or screws. Filter 110 may be coupled to one of the first side 104A and the second side 104B, such as to the first side 104A as depicted in FIGS. 1A-1C. The filter 110 may be any suitable filter that functions to filter particulates from the incoming gas flow. The filter 110 may filter particles having a particle size of 0.003 micron or more, and should exhibit low back pressure, such as less than about 5 psi at 5 slm, for example. Filter elements included in the filter 110 may include porous plastic, porous nickel, or porous stainless steel, for example. Other suitable filters 110 may be used.

As is shown in FIGS. 1A and 1C, the gas flow control assembly 100 may be configured as an inert gas control stick and may include an outlet conduit 109 coupled to the manifold 102, such as by bolts or screws. Outlet conduit 109 may include a fitting 109F on a first end and a mounting block 109M on a second end. The mounting block 109M may be fastened to the first side 104A of the manifold body 104 by bolts or screws or the like, for example. The fitting 109F may be coupled or interconnected to a process chamber (not shown).

The gas flow control assembly 100 may be configured to also include a mass flow controller (MFC) 114 coupled to the manifold 102, such as by bolts or screws. The MFC 114 may be coupled to one side of the manifold 102, such as to the first side 104A as shown.

The MFC 114 is a device used to measure and control the flow of a gas. The MFC 114 is designed and calibrated to control a specific or range of types of gas at a particular range of flow rates. The MFC 114 can be given a dynamically-adjustable set point from 0% to 100% of its full scale range, but may be operated at about 10% to about 90% of full scale where a best accuracy may be achieved. The MFC 114 may then be used to control the rate of flow to a predetermined flow ratio set point. MFCs 114 can be either analog or digital. A MFC 114 that is digital may be able to provide a higher degree of accuracy over a wider flow range, and may control more than one type of gas. Therefore, a MFC 114 may be digital in cases where more than one gas from a process gas supply is being supplied to the process chamber. A MFC 114 that is analog may also be used, but may be limited to a particular gas recipe for which it was calibrated.

The MFC 114 has an inlet port, an outlet port, an internal mass flow sensor, and an internal flow control valve. The MFC 114 may be fitted with a closed loop control system, which may be given a flow ratio set point control signal by a controller that is then compared to the value from the internal mass flow sensor and adjusts the flow control valve accordingly to achieve the predetermined flow rate. The flow ratio set point control signal may be specified as a percentage (a flow ratio) of its calibrated full scale flow. The flow ratio set point control signal may be supplied to the MFC 114 as a voltage from the controller, in analog models, or as serial data, in digital models. In some embodiments, the closed loop control system is provided as circuitry within the MFC 114, which is coupled to the controller and receives the flow ratio set point control signal therefrom.

In each depicted embodiment herein, the MFC 114 may be a mass flow controller of any suitable construction. The MFCs 114 may be capable of handling flow rates of between about 0.01 slm and 200 slm, for example. Other flow rate designs may be used.

Control valves 116A, 116B may be coupled to the manifold 202 on a side of the manifold 102 opposite from the MFC 114, such as to the second side 104B as shown. In this embodiment, the control valve 116B comprises an outlet valve. The control valves 116A, 116B may be coupled to the manifold 102, upstream and downstream of the MFC 114, as shown, such as by bolts or screws, and function to provide additional or redundant flow control, i.e., flow shutoff over and above that provided by inlet valve 108.

According to one or more embodiments, at least some of the inlet valve 108 and the filter 110 are coupled to a first side 104A, and the others of the inlet valve 108 and the filter 110 are coupled to a second side 104B.

For example, in the inert gas control stick configuration of FIGS. 1A-1C, the inlet conduit 107, filter 110, MFC 114, and outlet conduit 109 are all coupled to the first side 104A, and the inlet valve 108, control valves 116A, 116B (control valve 116B functioning as an outlet valve), are coupled to the second side 104B. As such, a much shorter length (L) of the overall gas flow control assembly 100 can be accomplished as compared to the prior art. The gas flow control assembly 100 may also include a mounting bracket 118 configured to mount the gas flow control assembly 100 to a structure, such as to a frame of a semiconductor processing tool. The bracket may be coupled top one of the first side 104A and the second side 104B. Between each of the components (e., inlet conduit 107, inlet valve 108, filter 110, control valves 116A, 116B, MFC 114, and outlet conduit 109) and the manifold 102, a sealing member may be used to seal gas escape at the interfaces thereof. Sealing member may be a gasket, O-ring, or other suitable sealing member.

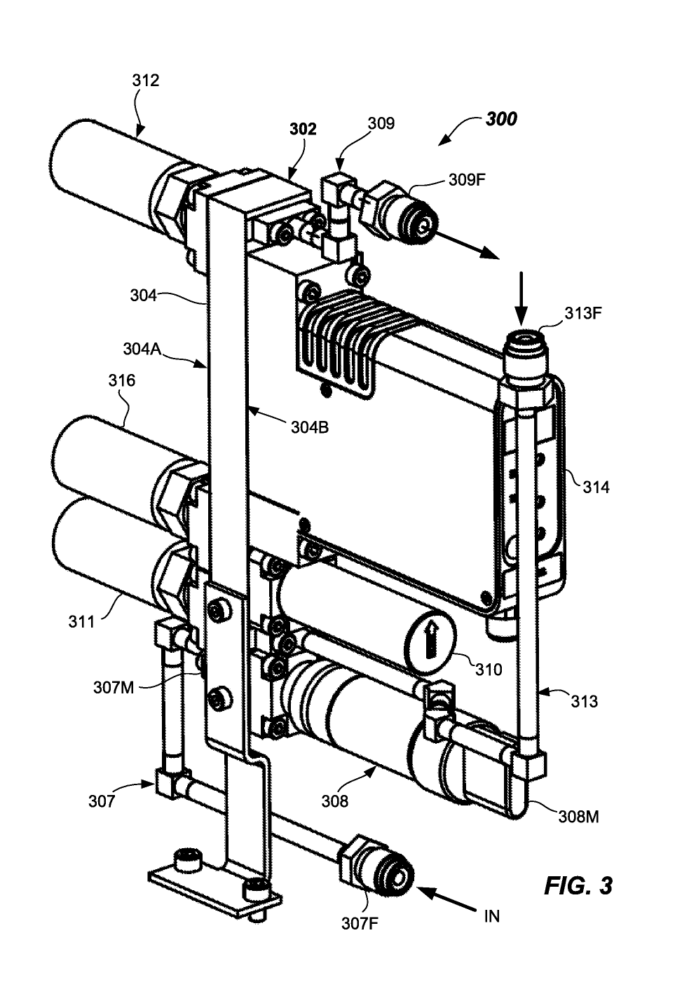

Another embodiment of a gas flow control assembly 300, which may be configured as a toxic gas flow stick assembly or a flammable gas flow stick assembly having a compact form factor (e.g., form factor=L/W<10; L/W<8; or even L/W<6 in some embodiments), is shown in FIG. 3. The gas flow control assembly 300 includes an inlet conduit 307 having a mounting block 307M coupled to a first side 304A of a manifold body 304 of a distribution manifold 302, such as by bolts or screws, and a fitting 307F configured to couple or interconnect (e.g., via another conduit—not shown) to a source of toxic or flammable gas (not shown). Gas flow control assembly 300 may include an inlet valve 308 coupled to a second side 304B of the manifold body 304. Inlet valve 308 may be a hybrid valve including remote pneumatic actuation and manually actuatable capability. Inlet valve 308 may include an actuation member 308M for opening or closing the inlet valve 308 for lockout and tag out. Gas flow control assembly 300 may include a pump/purge valve 311 coupled to the first side 304A of the manifold body 304. The pump/purge valve 311 may control the flow of purge gas entering through purge conduit 313. Purge conduit 313 may include a fitting 313F attached to its end. Purge gas (e.g., N₂) from a purge gas flow control assembly may be used to purge toxic or flammable gases from the portions of the gas flow control assembly 300 downstream of the inlet valve 308. In this manner, once purged, the components or gas lines can be removed or serviced. A filter 310 may be coupled to the second side 304B and provided upstream of a first control valve 316, wherein the first control valve 316 is coupled to the first side 304A. First control valve 316 controls gas flow into MFC 314 and may be a remotely actuatable valve.

The MFC 314, as previously described, may be operatively coupled to the distribution manifold 302 on the second side 304B. MFC 314 may be configured to receive gas flow from the first control valve 316 that may be coupled to the distribution manifold 302 on the first side 304A. An outlet valve 312 may be provided downstream of the MFC 314 and may be coupled to the distribution manifold 302 on the first side 304A thereof. An outlet conduit 309 may be coupled to the second side 304B of the distribution manifold 302 and a fitting 309F may be coupled (e.g., via another conduit—not shown) to a process chamber (not shown) to control gas flow to one or more zones of the process chamber. The process chamber may be any chamber where a process takes place on a substrate. Process chamber may function as an etch process chamber, a deposition process chamber (e.g., atomic layer deposition (ALD), physical vapor deposition (PVD), or chemical vapor deposition (CVD) deposition), a cleaning process chamber, or the like.

The substrate may be an electronic device precursor article, such as a semiconductor wafer, crystalline silicon wafer, silicon wafer, doped silicon wafer, doped or un-doped polysilicon wafers, masked silicon wafer, patterned or un-patterned silicon wafer, or a silicon-containing disc, silicon-containing plate, silicon-containing panel, other silicon-containing article, or the like. Substrate may be stationed and supported for processing on a suitable support within the process chamber, such as a pedestal or lift pins, for example. Thus, the process chamber may be a semiconductor processing chamber adapted to process a substrate therein.

Through the gas flow control assembly 300, the process gases delivered may be oxygen (O₂), nitrogen oxide (NO), nitrous oxide (N₂O), nitrogen dioxide (NO₂), CH₄, CHF₄, SF₆, C₄F₈, NF₃, H₂, NH₃, SiH₄, BCl₂, or Cl₂, or the like, for example. Other toxic or flammable gases may be handled by the gas flow control assembly 300.

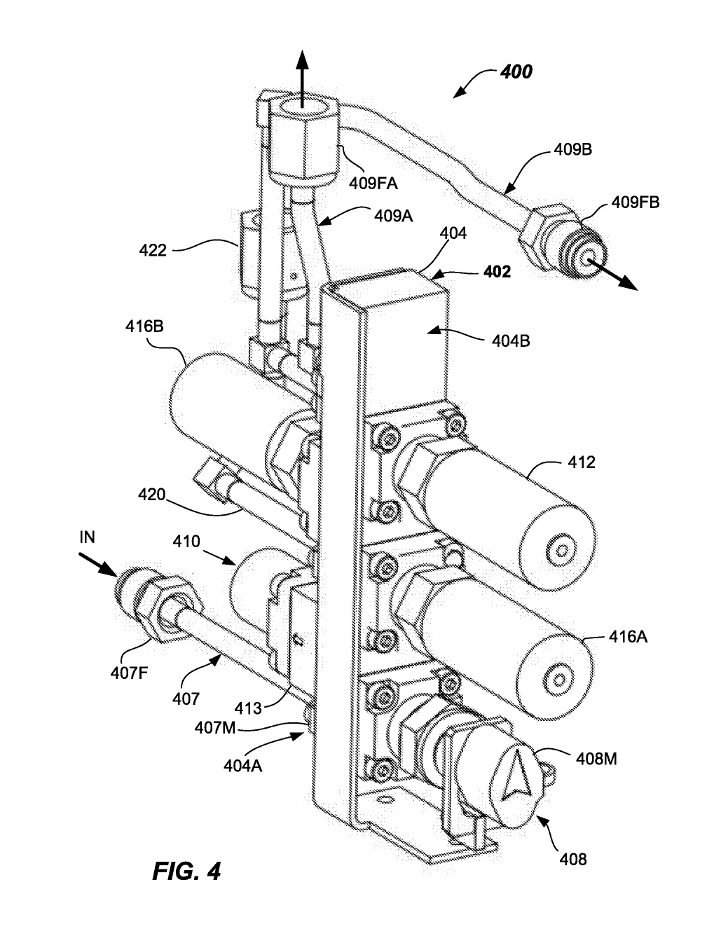

FIG. 4 illustrates another embodiment of a gas flow control assembly 400 having a compact form factor as described above. In the depicted embodiment, a distribution manifold 402 is provided having a manifold body 404 made of one-piece construction and which may include first and second sides 404A, 404B including flow passageways and orthogonal sides therefrom that may be devoid of flow passageways. The gas flow control assembly 400 includes an inlet conduit 407 having a mounting block 407M coupled to a first side 404A of the manifold body 404, such as by bolts or screws, and a fitting 407F configured to couple or interconnect to a source of purge gas (e.g., N₂). Gas flow control assembly 400 may include an inlet valve 408 coupled to a second side 404B of the manifold body 404. Inlet valve 408 may be a manually-actuatable valve and may include an actuation member 408M for opening or closing the inlet valve 408 for lockout and tagout. Other types of inlet valves may be used.

Gas flow control assembly 400 may further include a filter 410 coupled to the first side 404A of the distribution manifold 402. An intervening coupling member 413 may be used in some embodiments. The coupling member 413 may serve to provide a function of a check valve to minimize or eliminate back flow. Gas flow control assembly 400 may further include a first control valve 416A coupled to the second side 404B of the manifold body 404. The first control valve 416A may operate to control the flow of purge gas entering into a second control valve 416B and outlet valve 412. Purge gas (e.g., N₂) may be used to purge toxic or flammable gases from portions of another gas flow assembly (e.g., gas flow control assembly 300) or one or more process chambers. In this manner, once purged, the components, gas conduits, and one or more process chambers can be serviced.

First control valve 416A may be coupled to the second side 404B and may control gas flow in, and may be a remotely actuatable valve. Second control valve 416B may be coupled to the first side 404A and may control gas flow through a first outlet conduit 409A to fitting 409FA and may be a remotely actuatable valve. Second control valve 416B may be opened to ventilate the process chamber (not shown) with purge gas for a chamber service. A second outlet conduit 409B may include a fitting 409FB that may be coupled to another gas flow control assembly, for example, such as to gas flow control assembly 100 to supply purge gas thereto. A third conduit 420 including fitting 422 may be used to purge yet another component, such as another gas flow control assembly. For example, third conduit 420 may supply N₂ purge gas to flow through a gas flow control assembly 300 to purge a toxic or flammable gas out of that gas flow control assembly 300 to allow the gas flow control assembly 300 to be disassembled for service. Control valve 416A may control gas flow to the gas flow control assembly 400, while control valve 416B may provide purge gas to the process chamber. Control valves 416A, 416B may be pneumatically actuated and may be operated by an electro-valve (EV) manifold that operates small pilot valves based on digital or serial inputs, for example.

The gas flow control assembly 400 can connect to the process chamber, as well, allowing for the process chamber to be filled with N₂ and then evacuated. A gas flow control assembly 400 or process chamber to be serviced may be evacuated and filled with a purge gas (e.g., N₂) repeatedly to ensure that there is no hazard to the service engineer when it is disassembled.

The outlet valve 412 may be coupled to the distribution manifold 402. The outlet valve 412 may control gas flow through a second outlet conduit 409B and may be coupled to the second side 404B of the distribution manifold 402. Second outlet conduit 409B may include a fitting 409FB, which may be coupled to a process chamber (not shown) to control purge gas flow to one or more zones of the process chamber.

In each of the above embodiments, a controller may be coupled to the gas flow control assemblies 100, 300, 400 and may include a suitable processor, memory, software, firmware, or combinations, A/D converters, conditioning electronics, and drivers to control the gas flow through the various gas flow control assemblies 100, 300, 400. In cases where there is an MFC 114, 314, the desired flow set point may be set by the controller.

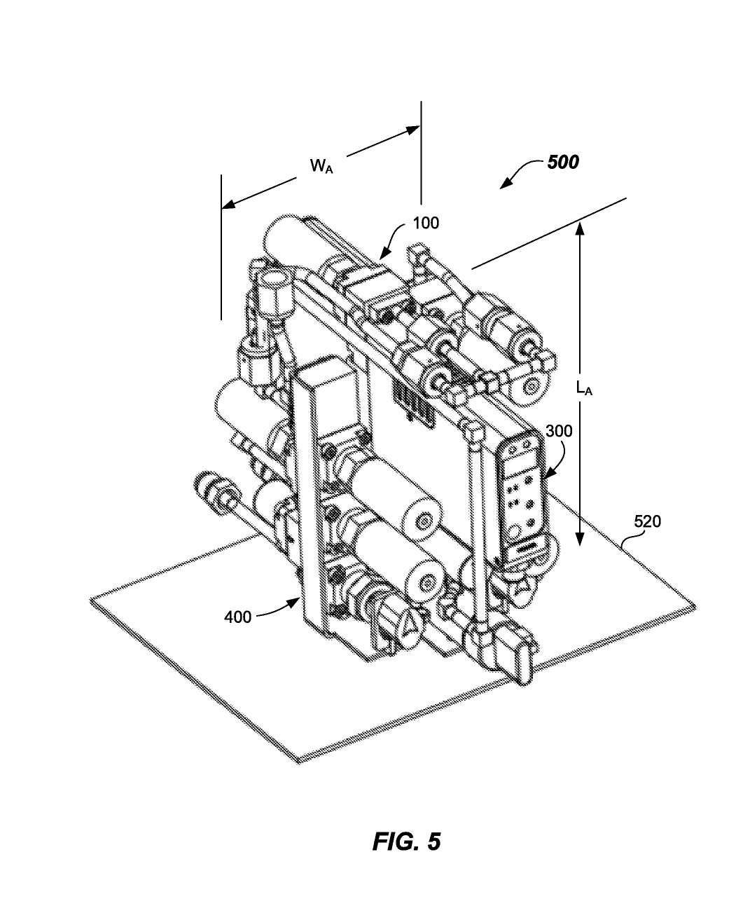

FIG. 5 illustrates a process gas control panel 500 having a compact panel form factor. The process gas control panel 500 includes multiple process gas control assemblies, such as a gas flow control assembly 100 embodied as an inert gas control assembly, a gas flow control assembly 300 embodied as a toxic or flammable gas control assembly, and a gas flow control assembly 400 embodied as purge gas control assembly. The gas flow control assemblies 100, 300, 400 may each be mounted to a common base 520 and may be arranged in a side-by-side configuration, as shown. The compact panel form factor (overall length (LA)/Overall Width (WA)) may be less than 3, or even less than 2.

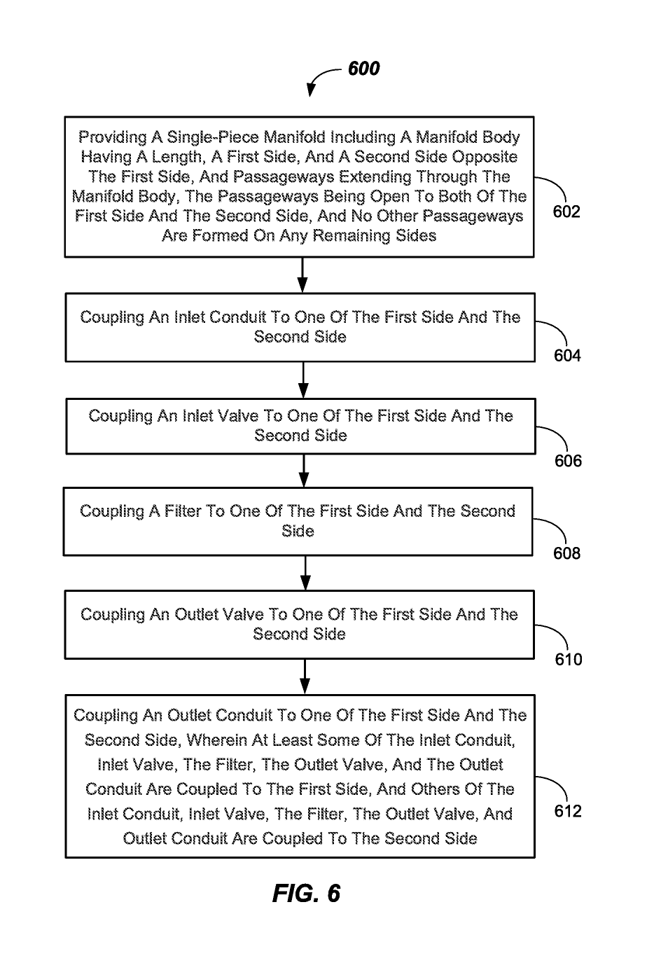

FIG. 6 illustrates a flowchart depicting an example method of assembly of a gas flow control assembly according to one or more embodiments of the present disclosure. The method 600 includes, in 602, providing a single-piece manifold (e.g., manifold 102) including a manifold body (e.g., manifold body 104) having a length L, a first side (e.g., first side 104A), and a second side (e.g., second side 104B) opposite the first side, and passageways (e.g., passageways 106A-106F) extending through the manifold body, the passageways (flow passageways) being open to both of the first side and the second side, and with no other passageways (flow passageways) formed on any remaining sides (e.g., the orthogonal sides.

The method 600 includes, in 604, coupling an inlet conduit (e.g., inlet conduit 107) to one of the first side and the second side, and in 606, coupling an inlet valve (e.g., inlet valve 108) to one of the first side and the second side. Further, the method includes, in 608, coupling a filter (e.g., filter 110) to one of the first side and the second side, and, in 110, coupling an outlet valve (e.g., outlet valve 112) to one of the first side and the second side.

The method 600 further includes, in 112, coupling an outlet conduit (e.g., outlet conduit 109) to one of the first side and the second side, wherein at least some of the inlet conduit (e.g., inlet conduit 107), inlet valve (e.g., inlet valve 108), the filter (e.g., filter 110), the outlet valve (e.g., outlet valve 112), and the outlet conduit (e.g., outlet conduit 109) are coupled to the first side, and others of the inlet conduit, inlet valve, the filter, the outlet valve, and outlet conduit are coupled to the second side. The other embodiments may be similarly assembled. Thus, a compact, low form factor (e.g., less than 10) which may be easily manufactured and assembled may be provided.

Note that although the above example method 600 is described as a sequence of discrete coupling steps, the disclosure is not so limited. The steps described are merely for illustrative purposes to facilitate understanding of one or more embodiments. Any number of additional or intermediate steps may be included, several steps may be omitted or combined, and any parts of any of the steps may be broken into sub-steps. In addition, the particular sequence in which the steps are presented is merely to facilitate understanding of the disclosure and it should be understood that these steps, or any combination or sub-steps, may be performed in any suitable order, including simultaneously.

Accordingly, while the present disclosure has been disclosed in connection with example embodiments thereof, it should be understood that other embodiments may fall within the scope of the disclosure, as defined by the appended claims.

What is claimed is:

1. A process gas control assembly, comprising:
a single-piece manifold including a manifold body having a length, a first side, and a second side opposite the first side, and passageways extending through the manifold body, the passageways being open to both of the first side and the second side, and no other passageways are formed on any remaining sides;
an inlet conduit coupled to one of the first side and the second side;
an inlet valve coupled to one of the first side and the second side;
a filter coupled to one of the first side and the second side;
an outlet valve coupled to one of the first side and the second side; and
an outlet conduit coupled to one of the first side and the second side; and
wherein at least some of the inlet conduit, inlet valve, the filter, the outlet valve, and the outlet conduit are coupled to the first side, and others of the inlet conduit, inlet valve, the filter, the outlet valve, and outlet conduit are coupled to the second side.

2. The process gas control assembly of claim 1, wherein some of the passageways extending through the manifold body include a central axis that is nonparallel with surfaces on the first side and the second side.

3. The process gas control assembly of claim 1, wherein some of the passageways extending through the manifold body are angled at a flow angle to the first side of between about 1 and 20 degrees.

4. The process gas control assembly of claim 1, comprising a mass flow controller coupled to the first side or the second side.

5. The process gas control assembly of claim 4, comprising control valves coupled to one of the first side or the second side on a side opposite the mass flow controller.

6. The process gas control assembly of claim 1, comprising the inlet valve on the second side and the outlet valve on the first side.

7. The process gas control assembly of claim 1, comprising an inert gas control assembly wherein the inlet valve is coupled to the second side, the outlet valve is coupled to the second side, and comprising a mass flow controller coupled to the first side, and a flow control valve coupled to the second side.

8. The process gas control assembly of claim 7, wherein the inert gas control assembly includes a first flow control valve on the second side configured to control flow into the mass flow controller.

9. The process gas control assembly of claim 1, comprising an inlet conduit coupled to the first side and an outlet conduit coupled to the first side.

10. The process gas control assembly of claim 1, comprising a mounting bracket coupled to one of the first side and the second side.

11. The process gas control assembly of claim 1, comprising an toxic or flammable gas control assembly wherein the inlet valve is coupled to the second side, the outlet valve is coupled to the first side, a mass flow controller is coupled to the second side, a purge flow conduit is coupled to the second side, and a purge flow valve is coupled to the first side.

12. The process gas control assembly of claim 1, comprising an purge gas control assembly wherein the inlet conduit is coupled to the first side, the inlet valve is coupled to the second side, the filter is coupled to the first side, the outlet valve is coupled to the second side; and the outlet conduit is coupled to the first side.

13. The process gas control assembly of claim 12, comprising a check valve coupled to the filter.

14. The process gas control assembly of claim 12, comprising a second outlet conduit coupled to the first side.

15. A process gas control panel, comprising a process gas control assembly of claim 1.

16. A process gas control panel of claim 15, further comprising an inert gas control assembly.

17. A process gas control panel of claim 15, further comprising a purge gas control assembly.

18. A process gas control panel of claim 15, further comprising a toxic gas control assembly or flammable gas control assembly.

19. A process gas control assembly, comprising:
a single-piece manifold including a manifold body having a length, a first side, and a second side opposite the first side, and passageways extending through the manifold body, the passageways being open on both of the first side and the second side, and no other passageways are formed on any remaining sides;
an inlet conduit coupled to a first side;
an inlet valve coupled to the second side;
a filter coupled to the first side;
a first control valve coupled to the second side;
a mass flow controller coupled to the first side;
a second control valve coupled to the second side;
an outlet valve coupled to the first side; and
an outlet conduit coupled to the second side.

20. A method of assembly of a gas flow control assembly, comprising:
providing a single-piece manifold including a manifold body having a length, a first side, and a second side opposite the first side, and passageways extending through the manifold body, the passageways being open to both of the first side and the second side, and no other passageways are formed on any remaining sides;
coupling an inlet conduit to one of the first side and the second side;
coupling an inlet valve to one of the first side and the second side;
coupling a filter to one of the first side and the second side;
coupling an outlet valve to one of the first side and the second side; and
coupling an outlet conduit to one of the first side and the second side,
wherein at least some of the inlet conduit, inlet valve, the filter, the outlet valve, and the outlet conduit are coupled to the first side, and others of the inlet conduit, inlet valve, the filter, the outlet valve, and outlet conduit are coupled to the second side.
